(19) United States
(12) Patent Application Publication
(10) Pub. No.: US 2025/0366025 A1
(43) Pub. Date: Nov. 27, 2025

(54) SUPERJUNCTION TRANSISTOR DEVICE

(71) Applicant: Infineon Technologies AG, Neubiberg (DE)

(72) Inventors: Caspar Leendertz, München (DE); Andreas Vörckel, Finkenstein (AT); Kristijan Luka Mletschnig, Klagenfurt (AT); Rudolf Elpelt, Erlangen (DE)

(21) Appl. No.: 19/208,717

(22) Filed: May 15, 2025

(30) Foreign Application Priority Data
May 23, 2024 (DE) 102024204771.6

(51) Int. Cl. H10D 30/66; H10D 62/10; H10D 62/60; H10D 62/832

(52) U.S. Cl. CPC H10D 30/665; H10D 30/668; H10D 62/106; H10D 62/108; H10D 62/127; H10D 62/60; H10D 62/8325

(57) ABSTRACT

Disclosed is a transistor device that includes: a source node; a drain node; a semiconductor body having an inner region and an edge region; a superjunction region having first regions of a first doping type and second regions of a second doping type arranged alternatingly in a first lateral direction of the semiconductor body; transistor cells arranged in the inner region; current spreading regions of the first doping type each arranged between a respective transistor cell and a respective first region; and third regions of the second doping type arranged in the inner region and the edge region, and spaced apart from each other in the first lateral direction. The first regions are coupled to the drain node. Each third region is coupled to the source node, adjoins a respective one of the second regions, and, in the inner region, adjoins at least one of the current spreading regions.

### TECHNICAL FIELD

This disclosure relates in general to a transistor device, in particular a SiC superjunction transistor device.

### BACKGROUND

There is a need to provide a superjunction transistor device with a high avalanche robustness.

### SUMMARY

One example relates to a transistor device. The transistor device includes a source node, and a drain node, a semiconductor body with an inner region and an edge region, a superjunction region with first regions of a first doping type and second regions of a second doping type arranged alternatingly in a first lateral direction of the semiconductor body, a plurality of transistor cells arranged in the inner region, a plurality of current spreading regions of the first doping type each arranged between a respective transistor cell and a respective first region, and a plurality of third regions of the second doping type arranged in the inner region and the edge region and spaced apart from each other in the first lateral direction. The first regions are coupled to the drain node. Each of the third regions is coupled to the source node, adjoins a respective one of the second regions, and, in the inner region, adjoins at least one of the current spreading regions.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of one portion of a superjunction transistor device that includes transistor cells in an inner region of a semiconductor body and an edge region laterally is surrounding the inner region;

FIG. 2 illustrates a horizontal cross-sectional view of a transistor device of the type illustrated in FIG. 1 in a portion of the device that includes parts of the inner region and the edge region in a corner of the semiconductor body;

FIGS. 3 and 4 illustrates transistor cells according to different examples;

FIGS. 5 and 6 illustrates top views of a transistor device of the type illustrated in FIG. 1 according to different examples;

FIG. 7 illustrates a vertical cross-sectional view of a transistor device of the type illustrated in FIG. 1 that shows a first section of the edge region in detail;

FIG. 8 illustrates a vertical cross-sectional view of a transistor device of the type illustrated in FIG. 1 that shows a second section of the edge region in detail;

FIG. 9 illustrates a vertical cross-sectional view of a transistor device of the type illustrated in FIG. 1 that shows a third section of the edge region in detail;

FIG. 10 shows a horizontal cross-sectional view of a transistor device of the type illustrated in FIG. 1 according to one example;

FIGS. 11-13 illustrate different examples of a superjunction region arranged in the inner region; and

FIGS. 14A-15B illustrate different examples of a superjunction region arranged in the edge region.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

As explained in the following, one example relates to a transistor device. The transistor device includes a source node, and a drain node, a semiconductor body with an inner region and an edge region, a superjunction region with first regions of a first doping type and second regions of a second doping type arranged alternatingly in a first lateral direction of the semiconductor body, a plurality of transistor cells arranged in the inner region, a plurality of current spreading regions of the first doping type each arranged between a respective transistor cell and a respective first region, and a plurality of third regions of the second doping type arranged in the inner region and the edge region and spaced apart from each other in the first lateral direction. The first regions are coupled to the drain node. Each of the third regions is coupled to the source node, adjoins a respective one of the second regions, and, in the inner region, adjoins at least one of the current spreading regions.

Each transistor cell may include a gate electrode arranged in a gate trench and connected to a gate node, a gate dielectric dielectrically insulating the gate electrode from the semiconductor body, a source region of the first doping type connected to the source node; and a body region of the second doping type arranged between the source region and a respective one of the current spreading regions.

The transistor device may further include a plurality of first connection regions of the second doping type, each connecting at least one of the third regions in the inner region to the source node. Each of the first connection regions may adjoin the gate dielectric of a respective transistor cell on one side of the gate trench, and the body region of the transistor cell may adjoin the gate dielectric on an opposite side of the gate trench.

Furthermore, the transistor device may include at least one second connection region of the second doping type connecting the third regions in the edge region to the source node.

The edge region may include a first section, a second section, and a third section, wherein the first section adjoins the inner region, wherein the third section adjoins side surfaces of the semiconductor body, wherein at least portions of some of the third regions and a portion of the superjunction region are arranged in the first section, wherein a portion of the superjunction region is arranged in the second section, wherein the second section is devoid of the third regions, and wherein the third section is devoid of the third regions and the superjunction region.

The transistor device may further include field rings of the second doping type in the edge region. The field rings may be arranged in the second and third sections of the edge region.

The third regions in the inner region at least approximately may have the same depth, width, and dopant dose as the third regions in the edge region.

A lateral dopant charge of the first regions may decrease in the edge region towards edge surfaces of the semiconductor body, and a lateral dopant charge of the second regions may decrease in the edge region towards edge surfaces of the semiconductor body.

The transistor device may further include inactive transistor cells in the edge region.

The semiconductor body of the transistor device may include silicon carbide, SiC.

The transistor device may further include a drain region of the first doping type, wherein the drain region coupled is connected to the drain node or forms the drain node and is coupled to the superjunction region and the drain node. Furthermore, the transistor device may include a buffer region of the first doping type arranged between the superjunction region and the drain region, wherein a doping concentration of the buffer region is lower than a doping concentration of the drain region. The buffer region may include a first buffer region section adjoining the superjunction region, and a second buffer region section arranged between the first buffer region section and the drain region, wherein the first buffer region section has a lower doping concentration than the second buffer region section.

The transistor device may further include a source electrode formed above a first surface of the semiconductor body, wherein the source electrode is connected to the source node or forms the source node and is connected to the source and body regions of the transistor cells.

The transistor device may further include a gate runner formed above a first surface of the semiconductor body in the edge region and connected to the gate electrodes of the transistor cells.

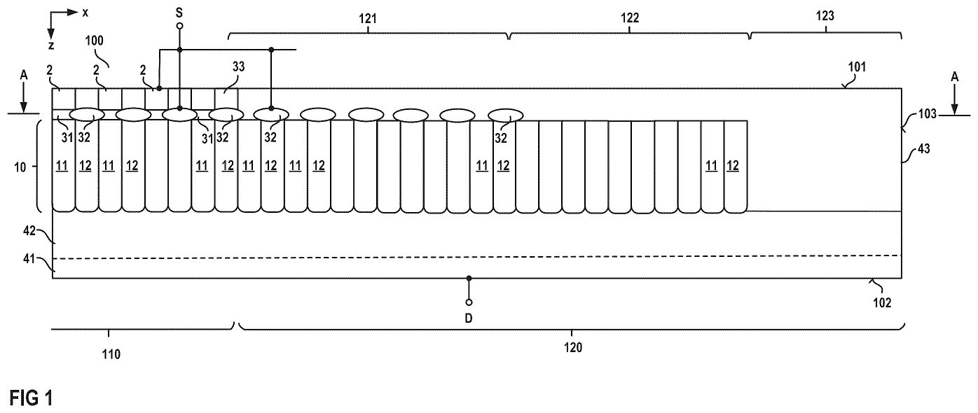

FIG. 1 illustrates one portion of a superjunction (SJ) transistor device according to one example. The transistor device includes a semiconductor body 100 with a first surface 101, a second surface 102 opposite the first surface 101, and an edge surface 103 extending between the first and second surfaces 101, 102 and laterally surrounding the semiconductor body 100. FIG. 1 schematically illustrates a vertical cross-sectional view of one portion of the semiconductor body 100. The vertical section plane illustrated in FIG. 1 is essentially perpendicular to the first and second surfaces 101, 102.

The semiconductor body 100 includes a monocrystalline semiconductor material. The semiconductor material is silicon (Si) or silicon carbide (SiC), for example.

Referring to FIG. 1, the semiconductor body 100 includes an inner region 110 and an edge region 120. The edge region 120 is arranged between the inner region 110 and the edge surface 103 and laterally surrounds the inner region 110. That is, the edge region 120 surrounds the inner region 110 in lateral directions, which are directions that are essentially parallel to the first and second surfaces 101, 102.

The transistor device includes a superjunction region 10 that includes first regions 11 of a first doping type and second regions 12 of a second doping type complementary to the first doping type. The first and second regions 11, 12 are arranged alternatingly in a first lateral direction x of the semiconductor body 100. According to one example, the superjunction region 10 is arranged in the inner region 110 and at least in portions of the edge region 120.

The transistor device further includes a plurality of transistor cells 2 arranged in the inner region 110, a plurality of current spreading regions 31 of the first doping type arranged in the inner region 110, and a plurality of third regions 32 of the second doping type. The transistor cells 2 are only schematically illustrated in FIG. 1. More detailed examples of the transistor cells are explained herein further below.

Each of the current spreading regions 31 is arranged between a respective transistor cell 2 and a respective first region 11. The third regions 32 are arranged in the inner region 110 and the edge region 120 and are spaced apart from each other in the first lateral direction x. Furthermore, each of the third regions 32 adjoins a respective one of the second regions 12 and, in the inner region 110, adjoins at least one of the current spreading regions 31. In the example illustrated in FIG. 1, the current spreading regions 31 and the third regions 32 are arranged alternatingly in the inner region 110, so that each current spreading regions 31 is arranged between two neighboring third regions 32.

The transistor device further includes a source node S and a drain node D, which are only schematically illustrated. The first regions 11 of the superjunction region 10 are coupled to the drain node D, and the third regions 32 are coupled to the source node S. For the ease of illustration, connections between the source node S and only one of the third regions 32 in the inner region 110 and only one of third regions 32 in the edge region 120 are illustrated in FIG. 1. More detailed examples in which way the third regions 32 are connected to the source node S are explained herein further below.

According to one example, the first regions 11 are connected to the drain node D via at least one semiconductor region of the first doping type. According to one example the at least one semiconductor region of the first doping type is a drain region 41 connected to the drain node D. The drain node D is formed by a metallization formed on top of the drain region 41, for example.

The drain region 41 may adjoin the first and second regions 11, 12. Optionally, as illustrated in dashed lines in FIG. 1, a buffer region (socket region) 42 of the first doping type is arranged between the drain region 41 and the first and second regions 11, 12. The optional buffer region 42 has a lower doping concentration than the drain region 41. The doping concentration of the drain region is in a range of between 5E18 cm⁻³ and 5E19 cm⁻³, for example. The doping concentration of the buffer (socket) region is in a range of between 3E15 cm⁻³ and 3E18 cm⁻³. The buffer region 42 may include two differently doped sections, a first section adjoining the first and second regions 11, 12, and a second section arranged between the first section and the drain region 41. The first section may have a lower doping concentration than the second section.

The transistor device can be operated in an on-state or an off-state. In the on-state, the transistor cells 2 provide for a conducting path between the source node S and the current spreading regions 31 so that the current can flow between the drain and source node D, S via the transistor cells 2, the current spreading regions 31, the first regions 11 of the superjunction region 10, the optional buffer region 42, and the drain region 41. In the off-state, a connection between the source node S and the current spreading regions 31 is interrupted. In this operating mode, when applying a voltage between the drain and source nodes D, S, PN junctions that are formed between the first and second regions 11, 12 are reverse biased so that, in accordance with the superjunction principle, the first and second regions 11, 12 are depleted of charge carriers. The second regions 12 of the superjunction region 10 are connected to the source node S via the third regions 32.

In the off-state, the third regions 32 protect the transistor cells 2 against high electric fields that may occur in the off-state in regions of the semiconductor body 100 close to the transistor cells 2. This is explained in detail herein further below. Thus, the third regions 32 are also referred to as shielding regions in the following. The first regions 11 of the superjunction region 10, which conduct a current in the on-state of the transistor device, may also be referred to as a drift regions, and the second regions 12 may also be referred to as compensation regions.

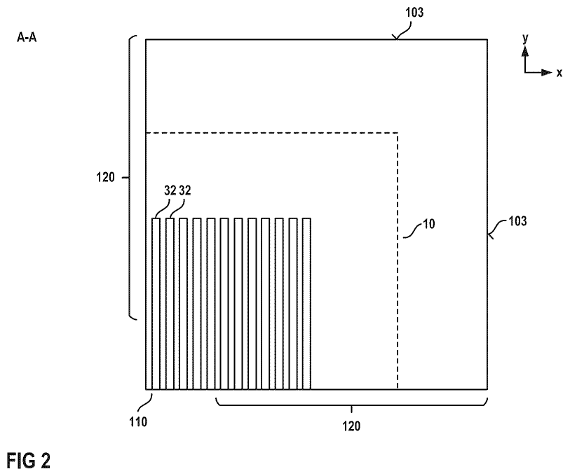

FIG. 2 shows a horizontal cross-sectional view of the transistor device according to FIG. 1 in a horizontal sectional plane A-A that cuts through the current spreading regions 31 and the shielding regions 32. According to one example, the semiconductor body 100 has a rectangular shape. FIG. 2 shows a portion of the semiconductor body 100 that includes one corner of the semiconductor body. More specifically, FIG. 2 shows a portion of the semiconductor body 100 that includes one portion of the inner region 110 and portions of the edge region 120 arranged between the illustrated portion of the inner region 110 and sections of the edge surface 103 forming the illustrated corner.

Referring to the above and as illustrated in FIG. 2, the third regions 32 are arranged spaced apart from each other in the first lateral direction x. In a second lateral direction y, which is essentially perpendicular to the first lateral direction, the third regions 32 are elongated regions. A length of the third regions 32, which is the dimension of the third region 32 in the second lateral direction y, is much larger than a width of the third region 32, which is the dimension of the third regions 32 in the first lateral direction x. According to one example, the width of the third regions 32 is selected from between 0.5 micrometer (μm) and 4 micrometers, in particular from between 1.5 micrometers and 3 micrometers.

In each lateral direction x, y, the third regions 32 are spaced apart from the edge surface 103. According to one example, a distance between the third regions 32 and the edge surface 103 is between 100 micrometers (μm) and 350 μm, in particular between 150 μm and 300 μm, for example.

The position of the superjunction region 10 below the third regions 32 is illustrated in dashed lines in FIG. 2. According to one example, the superjunction region 10, in each lateral direction x, y, extends farther to the edge surface 103 than the third regions 32. According to one example, the superjunction region 10, in each lateral direction x, y is spaced apart from the edge surface 103. A distance between the superjunction region 10 and the edge surface is between 50 μm and 300 μm, in particular between 100 μm and 200 μm.

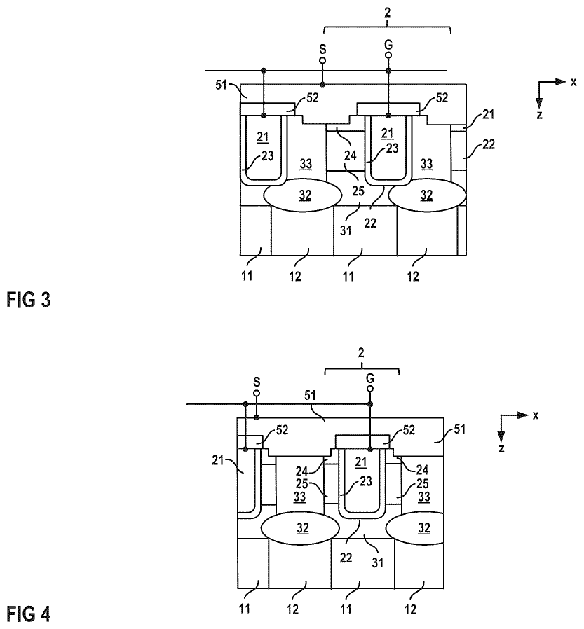

The transistor cells 2 for controlling the operating state (on-state or off-state) of the transistor device can be implemented in a conventional way. Two different examples for implementing the transistor cells 2 are illustrated in FIGS. 3 and 4.

In each of the examples illustrated in FIGS. 3 and 4, each transistor cell 2 includes a gate electrode 21 arranged in a gate trench 22 and connected to a gate node G; a gate dielectric 23 dielectrically insulating the gate electrode 21 from the semiconductor body 100; a source region 24 of the first doping type connected to the source node S; and a body region 25 of the second doping type arranged between the source region 24 and a respective one of the current spreading regions 31 and connected to the source node S. In each of FIGS. 3 and 4 several transistor cells are illustrated. The individual transistor cells are connected in parallel by having the source regions 24 connected to the source node S, by having the gate electrodes 21 connected to the gate node G, and by having the body regions 25 coupled to the drain node D via the current spreading regions 31, the first regions 11, the drain region 41 (not illustrated in FIGS. 3 and 4) and the optional buffer region 42.

The transistor device is in the on-state when a voltage is applied between the gate and source nodes G, S that causes conducting channels in the body regions 25 between the source and current spreading regions 24, 25 along the gate dielectrics 23 of the individual transistor cells 2. Thus, in the on-state, a current can flow between the source and drain nodes S, D via the source regions 25, the conducting channels in the body regions 25, the current spreading regions 31, the first regions 11, the drain region 41 and the optional buffer region 42.

The transistor device is in the off-state, when the conducting channels in the body regions 25 along the gate dielectrics 23 are interrupted. Referring to the above, first PN junctions are formed between the first regions 11, which are coupled to the drain node D, and the second regions 12, which are coupled to the source node S. Furthermore, second PN junctions are formed between the body regions 25, which are coupled to the source node S, and the current spreading regions 32, which are coupled to the drain node D via the first regions 11. Furthermore, third PN junctions are formed between the current spreading regions 31 and the third regions 32, which are coupled to the source node S. When, in the off-state, a voltage is applied between the drain and source nodes D, S that reverse biases these PN junctions space charge regions (depletion regions) are formed in the first and second regions 11, 12 of the superjunction region 10, the current spreading regions 31, the body regions 25, and the third regions 32.

According to one example, a doping of the first and second regions 11, 12 is such that the first and second regions 11, 12 can entirely be depleted of charge carriers in the off-state. According to one example, a doping of the current spreading regions 31 is such that the current spreading regions 31 can entirely be depleted of charge carriers in the off-state. The doping concentration of the current spreading regions 31 can be higher than, equal to, or lower than the doping concentration of the first regions 11.

The doping concentration of the third regions 32 is higher than the doping concentration of the second regions 12 of the superjunction region 10. In particular, a maximum doping concentration of the third regions 32 is higher than a maximum doping concentration of the second regions 12. Furthermore, according to one example, a doping of the third regions 32 is such that the third region 32 cannot entirely be depleted of charge carriers in the off-state.

In each of the examples illustrated in FIGS. 3 and 4, the third regions 32 and the current spreading regions 31 arranged between the third regions 32 form a JFET. The third regions 32 are gate regions of the JFET, and the current spreading regions 31 are channel regions of the JFET. The channel regions 31 are pinched off when a voltage is applied between the drain and starts nodes D, S that reverse biases the third PN junctions between the third regions 32 and the current spreading regions 31 and that causes the current spreading regions 31 to be depleted of charge carriers.

The third regions 32, as seen from the first surface 101, are arranged at least partially below bottoms 22 of the gate trenches. “Gate trenches” are the trenches in which the gate electrodes 21 and the gate dielectrics 23 are arranged. “Bottoms 22” of the gate trenches are those sections of the gate trenches that face away from the first surface 101.

A vertical dimension (depth) of the third regions 32 below the bottom 22 of the gate trenches is between 0.2 micrometers (0.2 μm) and 2 micrometers, in particular between 0.5 micrometers and 1.5 micrometers, for example. The “vertical dimension” is the dimension of the third regions 32 in the vertical direction z as measured from a horizontal plane that is defined by the vertical position of the bottoms 22 of the gate trenches. The bottoms 22 of the gate trenches are at the positions of an interface between the gate dielectric 23 in the respective gate trench and the semiconductor material adjoining the gate dielectric 23.

According to one example, the vertical dimension of the second regions 12, which is the dimension of the second regions 12 in the vertical direction z, is much larger than the vertical dimension of the third regions 32. According to one example the vertical dimension of the second regions 12 is at least 5 times already 10 times the vertical dimension of the third regions 32. The vertical dimension of the first regions 11 may correspond to the vertical dimension of the second regions 12.

A vertical implantation dose of the third regions 32 below the bottoms 22 of the gate trenches is between 0.5E14 cm⁻² and 4E14 cm⁻², in particular between 1E14 cm⁻² and 2E14 cm⁻², for example. “The implantation dose below the bottoms 22 of the gate trenches” is the integral of the doping concentration of the third regions 32 in the vertical direction z in the direction of the second surface 102 over the vertical dimension (depth) of the third regions 32 starting at a plane defined by the bottoms 22 of the gate trenches,

Referring to the above, the body regions 25 and the source regions 24 are connected to the source node S. In the examples illustrated, the transistor device includes a source electrode 51 formed above the first surface 101 of the semiconductor body 100. The source electrode 51 is connected to the source node S or forms the source node S of the transistor device. Furthermore, the source electrode is connected to the source regions 24 and is electrically insulated from the gate electrodes 21 by electrically isolating layers 52.

For connecting the source electrode 51 to the body regions 25 and the third regions 32, each transistor cell 2 includes a contact region 33 of the second doping type that is connected to the source electrode 51, adjoins the body region 25 of the transistor cell 2, and adjoins at least one third region 32. In this way, the third region 32 and the body regions 25 are connected to the source electrode 51 and the source node S via the contact regions 33.

The transistor cells according to FIGS. 3 and 4 are different from each other in several aspects.

In the example illustrated in FIG. 3, a body region 25 is arranged along only a first one of two opposite sidewalls of a gate trench. The “gate trench” is the trench in which the gate electrode 21 of the respective transistor cell 2 is arranged. The contact region 33 of the transistor cell 2 adjoins the body region 25 at a position that is spaced apart from the first sidewall of the gate trench and adjoins a second sidewall of the gate trench of a neighboring transistor cell. In this example, the number of transistor cells 2 equals the number of gate trenches.

In the example illustrated in FIG. 4, body regions 25 are arranged along first and second sidewalls of each gate trench. One contact region 33 adjoins the body regions 25 of two neighboring transistor cells 2 at positions spaced apart from each of the first and second sidewalls. In this example, the gate electrodes of 2 transistor cells are formed by one common gate electrode formed in a gate trench, so that the number of transistor cells is twice the number of gate trenches.

In each example, a current spreading region 31 is arranged between the body region 25 and the first region 11. The current spreading regions 31 “electrically connect” channel regions, which are those regions along the gate dielectric in which charge carriers flow in the on-state of the transistor device, with the first regions 11.

In the example illustrated in FIG. 3, each third region 32 adjoins the bottom 22 of a respective gate trench. In the example illustrated in FIG. 4, the third regions 32 are spaced apart from the bottoms 22 of the gate trenches.

The transistor device can be implemented as a normally-off (enhancement) device or as a normally-on (depletion) device. In a normally-off device, the body region 25 of the second doping type adjoins the gate dielectric 23. A normally-on device, in addition to the body region 25, includes a channel region (not illustrated) of the first doping type between the body region 25 and the gate dielectric 23.

The transistor device can be implemented as an N-type (N-channel) transistor device or as a P-type (P-channel) transistor device. In an N-type device, the first doping type is an N-type and the second doping type is a P-type. In a P-type device, the first doping type is a P-type and the second doping type is an N-type.

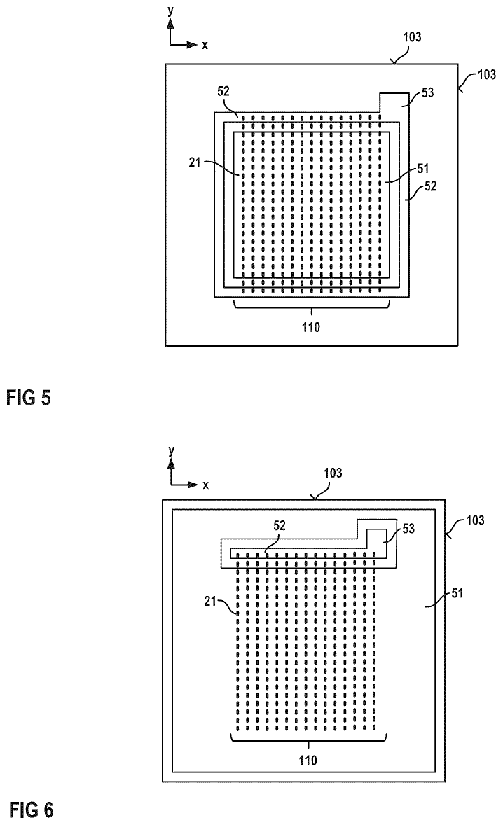

Referring to the above, the gate electrodes 21 are connected to the gate node G. Different examples for connecting the gate electrodes 21 2 the gate node G are illustrated in FIGS. 5 and 6. Each of FIGS. 5 and 6 schematically illustrates a top view of the transistor device with the source electrode 51 arranged above the first surface 101. The position of the gate electrodes 21 in the semiconductor body 100 below the source electrode 51 is illustrated in dashed lines in FIGS. 5 and 6. In both examples, the gate electrodes 21 are elongated electrodes that longitudinally extend in the second lateral direction y. In addition to the source electrode 51 the transistor device includes a gate runner 52 and a gate pad 53 adjoining the gate runner 52. The gate runner 52 and the gate pad 53 are electrically conducting and may be formed by the same electrical conductor. The gate runner 52 and the gate pad 53 are electrically insulated from the source electrode 51. Furthermore, the gate runner 52 and the gate pad 53 are electrically insulated from the semiconductor body 100. For this, the gate runner 52 and the gate pad 53 may be formed on top of an insulating layer formed above the first surface 101. The gate pad 53 forms the gate node G or is connected to the gate node of the transistor devices.

In the example according to FIG. 5, the gate runner 52 forms a closed loop and each of the gate electrodes 21 is connected to the gate runner 52 at both longitudinal ends. In the example according to FIG. 6, the gate runner 52 is arranged only above first longitudinal ends of the gate electrodes 21, so that the gate electrodes 21 are connected to the gate runner 52 only at the first longitudinal end.

In each case, the gate electrodes 21 can be connected to the gate runner 52 through electrically conducting vias (not illustrated in the drawings) that extend from the gate electrodes 21 to the gate runner 52 through the insulating layer on top of which the gate runner 52 and the gate pad 53 are formed.

Referring to FIG. 1, the edge region 120 may include three different edge region sections 121, 122, 123, a first section 121 adjacent to the inner region 110, a second region 122 adjacent to the first section 121 in the directions of the edge surface 103, and a third region 123 arranged between the second section 122 and the edge surface 103. Each of the first, second, and third sections 121, 122, 123 laterally surrounds the inner region 110.

The three edge region sections 121, 122, 123 are different from each other with regard to the individual device regions included therein. The first section 121 is that portion of the edge region 120 that includes the third regions 32. Furthermore, the first section 121 includes a portion of the superjunction region 10. The second section 122 includes another portion of the superjunction region 10, but is devoid of third regions 32. The third section 123 is devoid of both third regions 32 and the superjunction region 10.

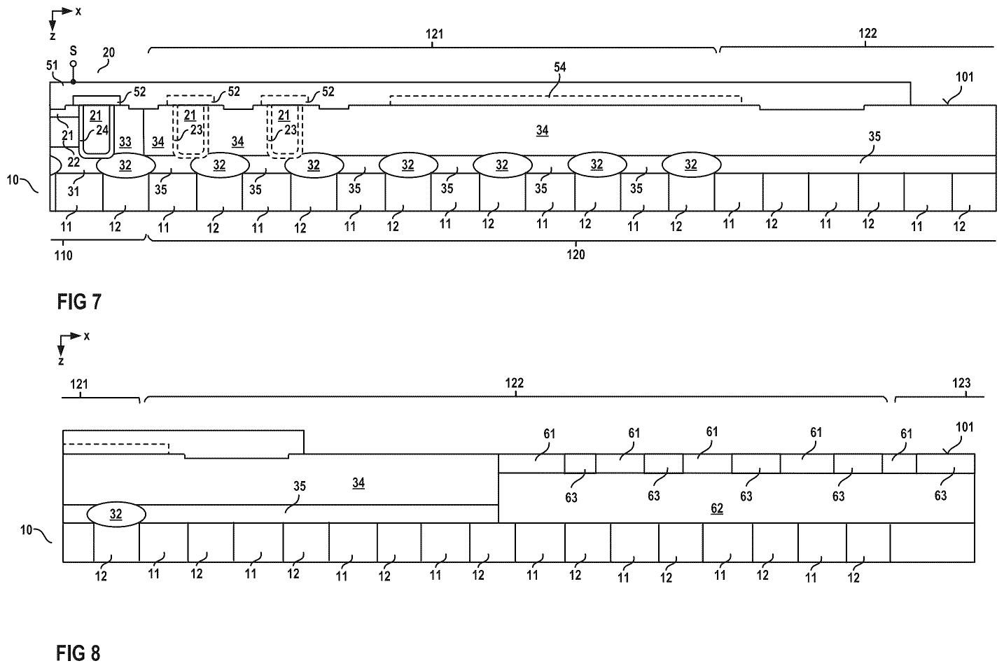

More detailed examples of the first, second, and third edge region sections 121, 122, 123 are illustrated in FIGS. 7-9. Each of FIGS. 7-9 illustrates a vertical cross-sectional view of the respective edge region section 121, 122, 123.

Referring to the above, the third regions 32 are connected to the source node S. This applies to both third regions 32 arranged in the inner region 110, and third regions 32 arranged in the edge region 120. As can be seen from FIG. 7, the third regions 32 arranged in the edge region 120 may be connected to the source electrode 51 via a contact region 34 of the second doping type. A portion of the source electrode 51 is arranged above the edge region 120 and is connected to the contact region 34. The contact region 34 extends from the first surface 101 down to the third regions 32. According to one example, the entire portion of the source electrode 51 formed above the edge region 120 is connected to the contact region 34. According to another example, illustrated in dashed lines in FIG. 7, some portions of the source electrode 51 are electrically insulated from the semiconductor body 100 in the edge region 120 by an insulating layer 54.

According to one example, the contact regions 33 in the inner region 110 and the contact region 34 in the edge region 120 are formed by the same process, so that the contact regions 33 in the inner region 110 and the contact region 34 in the edge region 120 may have the same doping profile in the vertical direction z. The third regions 33 adjoin the contact regions 33, 34 in the vertical direction in a direction facing away from the first surface 101. According to one example, a maximum of the doping concentration of each of the third regions 32 is located below the bottoms 22 of the gate trenches.

Referring to the above, in the inner region 110, neighboring third region 32 are separated from each other by the current spreading regions 31 of the first doping type. In the edge region 120, neighboring third regions 32 are separated from each other by fourth regions 35 of the second doping type. The fourth regions 35 have a lower (vertical) dopant dose than the third regions 32. That is, an integral of the doping concentration of the fourth regions 35 in the vertical direction z starting at a horizontal plane defined by the bottoms 22 of the gate trenches is lower than the respective integral of the doping concentration of the third regions 32. Each of the fourth regions 35 adjoins a respective first region 11 of the superjunction region 10. According to one example, the dopant dose of the fourth region 35 is such that the fourth region 35 can entirely be depleted of charge carriers when the transistor device is in the off-state.

Referring to FIG. 7, gate trenches (illustrated in dashed lines in FIG. 7) may be arranged in the first edge region section 121 in a region adjoining the inner region 110. The gate trenches with the gate electrodes 21 and the gate dielectric 23 in the edge region 120, however, are not electrically active. This is achieved by omitting source regions adjacent to sidewalls of the gate trenches in the edge region 120, and by omitting current spreading regions below the gate trenches in the edge region 120.

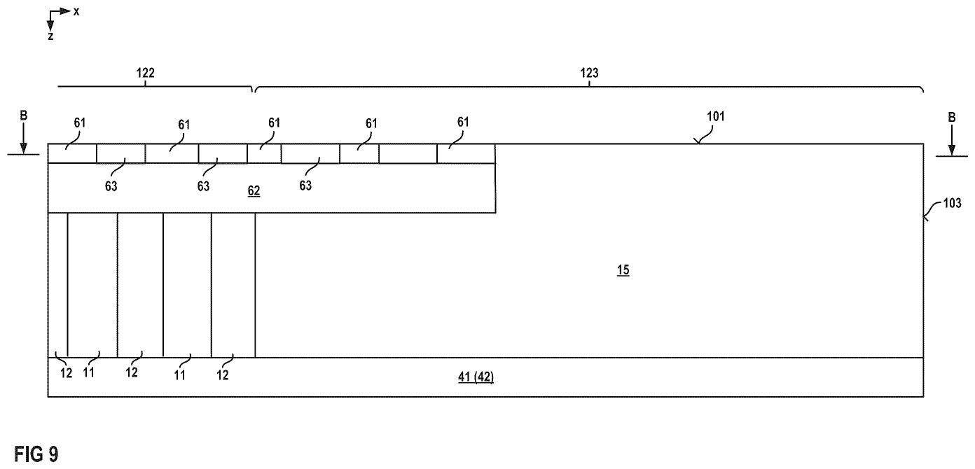

Referring to FIG. 8, the transistor device may include field rings 61 of the second doping type in the second edge region section 122. The field rings 61 adjoin the first surface 101. Furthermore, the field rings 61 are spaced apart from each other and are separated from one another by doped regions 63 of the first doping type. Each of the field rings 61 forms a closed loop in the horizontal plane in which the field rings 61 are arranged. The number of field rings 61 is between 3 and 15, in particular between 5 and 10, for example.

Referring to FIG. 8, the field rings 61 are spaced apart from the superjunction region 10 in the vertical direction z and are separated from the superjunction region 10 by a fifth region 62 of the second doping type. According to one example, the fifth region 62 adjoins the contact region 34. According to one example, a doping of the fifth region 62 is lower than doping concentrations of the feelings 61 and lower than the doping concentration of the conduct region 34. When the transistor device is in the off-state and a blocking voltage is applied between the drain and source nodes, a space charge region expands in the edge region such that, dependent on the type of transistor device, the electrical potential increases or a decreases towards the edge surface 103. In this operating scenario, the field rings 61 have different electrical potentials. The electrical potential of each field ring corresponds to the electrical potential of the space charge region at the position of the respective field ring 61.

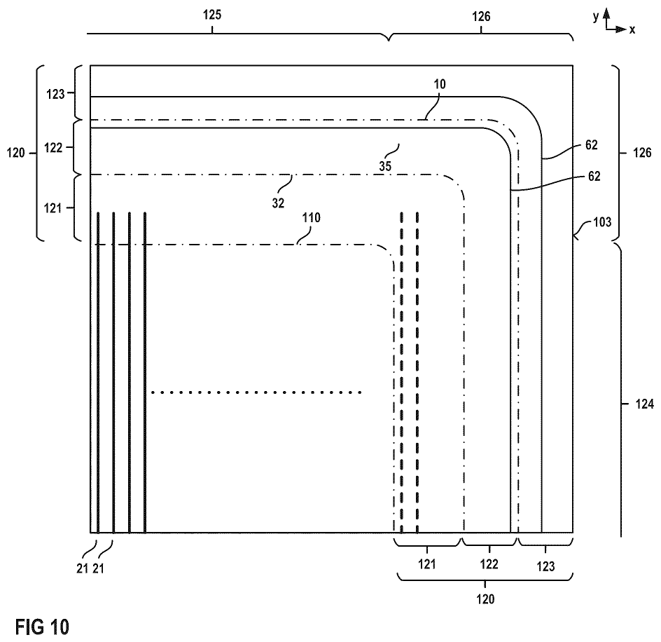

According to one example, the field rings 61 are arranged partially in the second edge region section 122 and the third edge region section 123. That is, some of the field rings 61 may be arranged in the second edge region section 122 above the superjunction region 10, and some of the field rings may be arranged in the third edge region section 123, which is devoid of the superjunction region 10. This is illustrated in FIGS. 8 and 9.

It should be noted that in FIGS. 7 and 8 only the portion of the superjunction region 10 adjoining the third regions 32 and the fourth regions 35 are illustrated. The drain regions 41 and the optional buffer region 42 are not shown.

In FIG. 9, a portion of the drain region 41 or the optional buffer region 42 adjoining the superjunction region 10 in the direction of the second surface 102 is illustrated. Referring to FIG. 9, in the third edge region section 123, the transistor device includes a sixth region 15 of the first doping type. A doping concentration of the sixth region 15 is lower than the doping concentration of the first regions 11. The doping concentration of the sixth region 15 is lower than the doping concentration of the first regions 11, for example. According to one example, the doping concentration of the sixth region 15 is between 5E15 cm⁻³ and 5E16 cm⁻³. Furthermore, the sixth region 15, in the vertical direction z, extends from the drain region 41 or the optional buffer region 42 to the first surface 101 or the fifth region 62 and, in the lateral direction, extends to the edge surface 103.

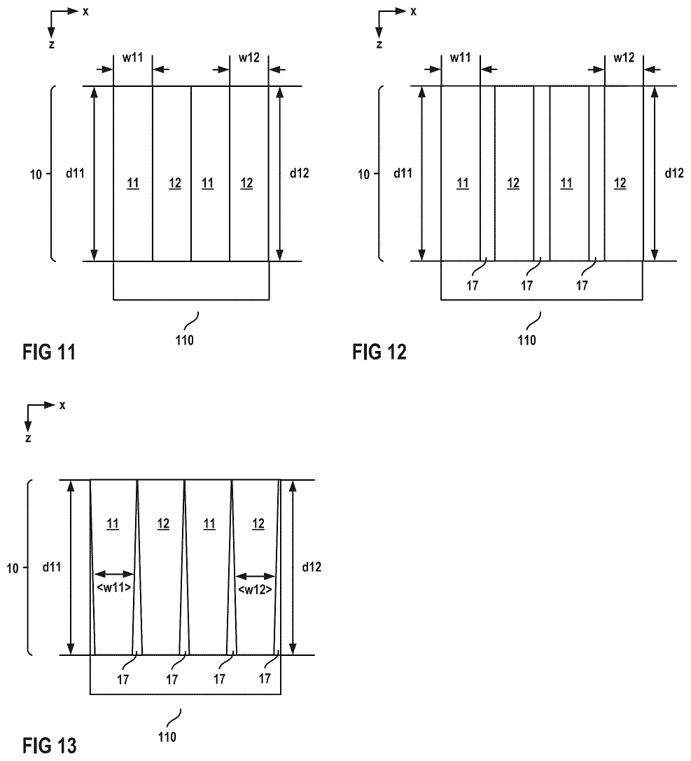

FIG. 10 shows a horizontal cross-sectional view of a section of the semiconductor body 100 that includes an edge region 120 in accordance with FIGS. 7-5. More specifically, FIG. 10 shows a horizontal cross-sectional view of one of four corner sections of the semiconductor body 100. In addition to portions of the edge region 120 a portion of the inner region 110 is also illustrated. In FIG. 10, the dashed-and-dotted lines illustrate borders between the inner region 110 and the first edge region section 121, between the first and second edge region sections 121, 122, and between the second and third edge region sections 122, 123. The bold lines illustrate some of the gate electrodes arranged in the inner region 110. The gate dielectrics 23 are not illustrated.

As can be seen from FIG. 10, in the second lateral direction y, the gate electrodes 21 extend into the edge region 120. The gate electrodes 21 are connected to the gate runner (not illustrated in FIG. 10) at longitudinal ends arranged in the edge region. According to one example, the edge region 120 is devoid of source regions, so that a current flow through the transistor cells 2 along the gate dielectrics 23 is restricted to the inner region 110. The bold dashed lines in FIG. 10 illustrate optional gate electrodes that are arranged in the edge region 120 next to the inner region 110 in the first lateral direction x and are entirely arranged in the edge region 120.

Referring to the above, the field rings 61 may be arranged in the second section 122 and the third section 123. For the ease of illustration, the field rings 61 are not illustrated in FIG. 10. FIG. 10, however, illustrates the fifth region 62 that is arranged below the field rings 61 in the second and third edge region sections 122, 123.

The elongated third region 32 in the inner region 110 and the edge region 120 may be formed by the same process. According to one example, forming the third region 32 includes an implantation process in which dopant atoms are implanted via the first surface 101 into the semiconductor body 100 using an implantation mask.

A conventional transistor device of the type illustrated in FIG. 1, includes a contiguous doped region of the second doping type that is formed in the same process as the shielding regions arranged in the inner region. Thus, the contiguous doped region of the second doping type has the same vertical dopant dose as the shielding regions in the inner region. In the conventional device, the presence of contiguous highly doped regions of the second doping type causes an abrupt PN junction between the first regions of the superjunction region and the contiguous region of the second doping type in the edge region. In the blocking state of the transistor device this may cause high electric fields and may result in a reduction of the voltage blocking capability of the transistor device in the edge region.

In the transistor device according to FIG. 7, in which the lower doped fourth regions 35 adjoin the first regions 11 in the direction of the first surface 101, and in which PN junctions are formed between the first regions 11 and the lower doped fourth regions 35, electric fields in the off-state are reduced as compared to a conventional device. This results in a higher voltage blocking of the transistor device in the edge region.

The voltage blocking capability of the transistor device is the maximum voltage that can be applied between the drain and source nodes D, S in the off-state without an Avalanche breakdown occurring. In the inner region 110, the voltage blocking capability is essentially defined by the vertical dimension of the superjunction region 10, the doping of the superjunction region 10, the vertical dimension of the optional buffer region 42 and its doping concentration. The edge region 120 is capable of withstanding the voltage applied between the drain node D and the source node S in the vertical direction and in the lateral direction between the edge surface 102 and the inner region 110. The lateral voltage blocking capability is required because the electrical potential at the edge surface 103 essentially corresponds to the electrical potential of the drain node D and the drain region 41.

According to one example, the transistor device is implemented such that the voltage blocking capability of the transistor device in the edge region 120 is higher than the voltage blocking capability in the inner region 110. In this example, when the voltage between the drain node D and the source node S in the off-state increases an Avalanche breakdown occurs in the inner region 110 before an Avalanche breakdown can occur in the edge region 120. Usually, the size of the inner region 110 is much larger than the size of the edge region 120. Thus, an Avalanche current that is as associated with an Avalanche breakdown occurring in the inner region 110 is distributed over a larger area than an Avalanche current associated with an Avalanche breakdown in the edge region. Moreover, an Avalanche breakdown in the edge region is usually associated with a locally concentrated (not homogeneously distributed) Avalanche current, which may even worsen the negative impact of an Avalanche breakdown occurring in the edge region. Thus, implementing the transistor device such that the Avalanche breakdown occurs in the inner region, makes the device more robust against Avalanche breakdowns.

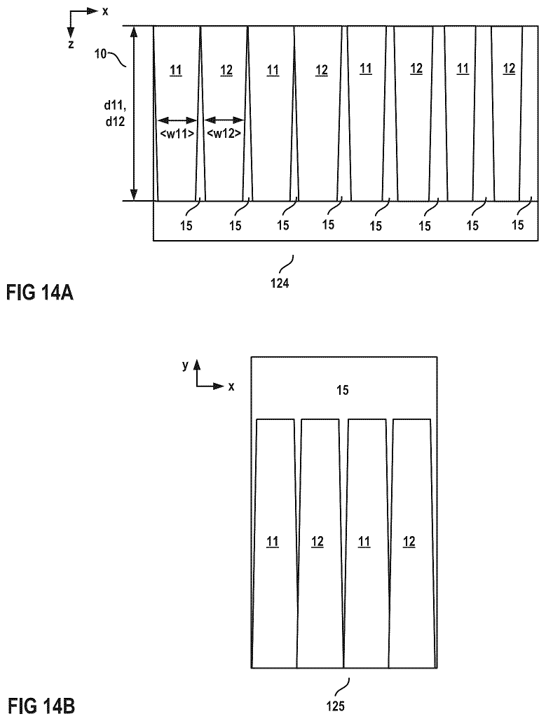

In the inner region 110, the first and second regions 11, 12 of the superjunction region 10 may be implemented in various ways. Different examples are illustrated in FIGS. 11-13. Each of these examples illustrates a vertical cross-sectional view of one portion of the superjunction region 10 in the inner region 110. In each of these examples, the first and second regions 11, 12 are arranged alternatingly in the first lateral direction x and are elongated in the second lateral direction y. In the following, w11 denotes a width of the first regions 11, which is a dimension of the first regions 11 in the first lateral direction x, and w12 denotes a width of the second regions 12, which is a dimension of the second regions 12 in the first lateral direction x. Furthermore, <w11> denotes an average width of each first region 11, and <w12> denotes an average width of each second region 12.

The first and second regions 11, 12 may have essentially the same width w11, w12 along the entire depth. The “depth” is the dimension of the first and second regions 11, 12 in the vertical direction z. Examples of first and second regions 11, 12 having the same width w11, w12 along the entire depth are illustrated in FIGS. 11 and 12.

In the example illustrated in FIG. 11, neighboring first and second regions 11, 12 adjoin one another, so that a PN junction is directly formed between neighboring first and second regions 11, 12. In the example illustrated in FIG. 12, neighboring first and second regions 11, 12 are separated by a doped region 17 of the first doping type. The doping concentration of this doped region 17 may correspond to the doping concentration of the sixth region 15 in the edge region 120 and is lower than the doping concentration of the first regions 11.

In the example illustrated in FIG. 13, the widths of the first and second regions 11, 12 decrease in the direction of the second surface 102 (not illustrated in FIG. 13). In this case, at least between portions of two neighboring first and second regions 11, 12 a doped region 17 of the first doping type is arranged.

The operating principles of the superjunction regions 10 illustrated in FIGS. 11-13 is the same. In each case, the first and second regions 11, 12 are depleted of charge carriers when the transistor device is operated in the off-state. In the examples illustrated in FIGS. 12 and 13, the doped regions 17 are also depleted.

In each of the examples illustrated in FIGS. 11-13, the first and second regions 11, 12 can be formed using an MEMI (multi-epi-multi-implant) process. In this type of process, several epitaxial layers are formed one above the other and first and second type dopant atoms are implanted into each of the epitaxial layers using implantation masks. After the epitaxial layers have been formed and the dopant atoms have been implanted the implanted dopant atoms are activated in a temperature process. The epitaxial layers may have a doping concentration that corresponds to the doping concentration of the doped 15 and 17, so that the doped regions 15 and 17 result from those regions of the epitaxial layers into which dopant atoms have not been implanted. An MEMI process is commonly known, so that no further explanation is required in this regard.

It should be noted that when using SiC as the material of the semiconductor body 100 the temperature process for activating the implanted dopant atoms does not result in a diffusion of the implanted dopant atoms. Thus, in SiC the doped regions resulting from implantation processes are as-implanted regions. That is, the shape of the doped regions corresponds to the shape of those regions into which dopant atoms have been implanted. In the MEMI process for forming the superjunction region 10 implanting the dopant atoms into each epitaxial layer may include several implantation processes using different implantation energies in order to implant the dopant atoms into different in depths of each epitaxial layer, so that in the finished device the first and second regions 11, 12 are contiguous regions in the lateral direction z.

According to one example, the first and second regions 11, 12 are formed such that in the inner region the doping concentration in the second lateral direction y is essentially homogeneous 110 at each vertical position. Furthermore, each of the first and second regions 11, has an effective lateral dopant dose 12 at each vertical position. The effective lateral dopant dose is the integral of the effective doping concentration in the first lateral direction x. The first and second regions 11, 12 can be implemented such that, in the inner region 110, the effective lateral dopant dose in each of the first and second regions 11, 12 is essentially the same at each vertical position. According to another example, the first and second regions 11, 12 are implemented such that the effective lateral dopant dose decreases towards the second surface 102 in the inner region 110. According to one example, neighboring first and second regions 11, 12 at each vertical position have essentially the same effective lateral dopant dose.

A length specific effective dopant charge of each of the first and second regions 11, 12 is the integral of the effective lateral dopant dose along the entire depth of the respective first and second regions 11, 12. In other words, the length specific dopant charge is the overall number of effective dopant atoms in one section of the first and second regions 11, 12 having a predefined length in the second lateral direction (which is the longitudinal direction of the first and second regions). The number of effective dopant atoms is given by the number of majority charge carriers minus the number of minority charge carriers in the respective first or second region 11, 12. In the first regions 11, first type dopant atoms form majority charge carriers and second type dopant atoms form minority charge carriers, wherein first type dopant atoms prevail in the first regions 11. In the second regions 12, second type dopant atoms form majority charge carriers and first type dopant atoms (which may result from the basic doping of the epitaxial layers) form minority charge carriers, wherein second type dopant atoms prevail in the second regions 12.

According to one example, the doping concentration in the first and second regions 11, 12 is essentially homogeneous at each vertical position in the inner region 110.

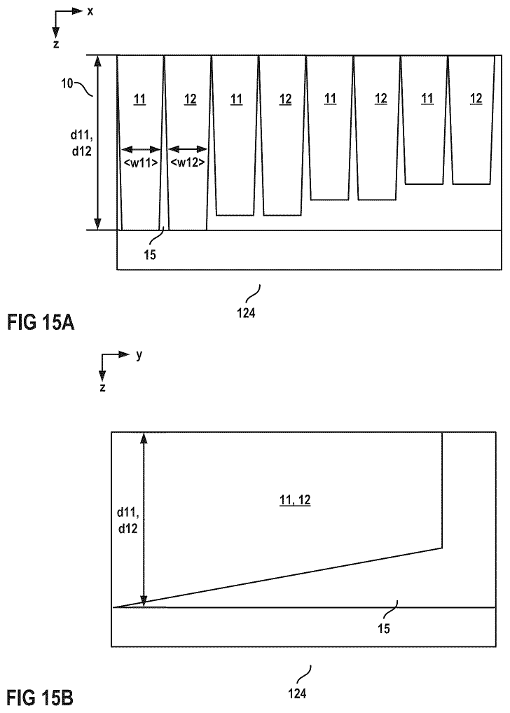

According to one example, the superjunction region 10 is implemented such that the length specific effective dopant charge in the first and second regions 11, 12 decreases in the direction of the edge surface 103. Different examples for implementing the first and second regions 11, 12 such that the length specific effective dopant charge decreases the directional the edge surface 103 are illustrated in FIGS. 14A-14B and 15A-15B and explained in the following.

According to one example, in the examples illustrated in FIGS. 14A-14B and 15A-15B, the doping concentration in the first and second regions 11, 12 is essentially homogeneous at each vertical position in the edge region 120.

Each of FIGS. 14A and 15A illustrates a vertical cross-sectional view of one portion of the superjunction region 10 arranged in a fourth edge region section 124. Referring to FIG. 10, the fourth edge region section 124 is a section of the edge region 120 that is arranged between the inner region 110 and the edge surface 103 in the first lateral direction x. The transistor device includes two fourth edge region sections 124 on opposite sides of the inner region 110. Each of FIGS. 14A and 15A shows a vertical cross-sectional view of the superjunction region 10 in a vertical section plane that is defined by the first lateral direction x and the vertical direction z.

Each of FIGS. 14B and 15B illustrates one portion of the superjunction region 10 arranged in a fifth edge region section 125. Referring to FIG. 10, the fifth edge region section 125 is a section of the edge region 120 that is arranged between the inner region 110 and the edge surface 103 in the second lateral direction y. The transistor device includes two fifth edge region sections 125 on opposite sides of the inner region 110. FIG. 14B shows a horizontal cross-sectional view of one portion of the superjunction region 10 in the fifth edge region section 125, and FIG. 15B shows a vertical cross-sectional view of a first region 11 or a second region 12 in the fifth edge region section 125 in a section plane defined by the second lateral direction y and the vertical direction z.

Referring to FIG. 10, in addition to the fourth and fifth edge region sections 124, 125, the transistor device further includes sixth edge region sections 126. The transistor device includes four sixth edge region sections 126, wherein each of these sixth edge region sections 126 is located in a corner of the semiconductor body 100 and adjoins a respective one of the fourth edge region sections 124 and the fifth edge region sections 125.

In the example illustrated in FIGS. 14A and 14B the decrease of the length specific effective dopant charge is achieved by implementing the first and second regions 11, 12 such that the average width <w11>, <w12> decreases in the direction of the edge surface. In the fourth edge region section 124, this includes that at least one first region 11 has a smaller average width <w11> than another first region 11 arranged closer to the inner region 110. According to one example, at least five first regions 11 have different average widths <w11> such that the closer the respective first region 11 is arranged to the edge surface 103 in the first lateral direction x, the lower the respective average width <w11>. Furthermore, this includes that that at least one second region 12 has a smaller average width <w12> than another second region 12 arranged closer to the inner region 110. According to one example, at least five second regions 12 have different average widths <w12> such that the closer the respective first region 11 is arranged to the edge surface 103 in the first lateral direction x, the lower the respective average width <w11>.

According to one example, the transistor device includes pairs with one first region 11 and one neighboring can region 12 in the fourth edge region 124 such that the neighboring first and second regions 11, 12 essentially have the same length specific effective dopant charge. In this way, the effective overall amount of first type dopant charges in the first region 11 essentially equals the effective overall amount of second type dopant charges in the neighboring second region 12, so that the first and second regions 11, 12 can be entirely depleted of charge carries in the off-state. According to one example, the length specific effective dopant charge of the second region 12 in each pair is slightly higher than the length specific effective dopant charge of the neighboring first region 11. This takes into account that the first and second regions 11, 12 may be separated by doped regions 17 of the first doping type. The higher dopant charge in the second regions 12 ensures that these doped regions 12 are depleted in the off-state.

Referring to FIG. 14B, the decrease of the length specific effective dopant charge of the first and second regions 11, 12 125 in the second lateral direction y in the fifth edge region section includes that the width w11, w12 of each first and second region 11, 12 at each vertical position decreases towards the edge surface 103. According to one example, the transistor device includes pairs with one first region 11 and one neighboring second region 12 in the fifth edge region section 125 such that the neighboring first and second regions 11, 12 essentially have the same width profile. According to one example, each second region 12 at each lateral position in the second lateral direction y is slightly wider than the neighboring first region 11. In this way, the length specific dopant charge of the second region 12 is higher than the length specific dopant charge of the neighboring first region 11 and the effective overall amount of second type dopant charges and the second region 12 is higher than the effective overall amount of first type dopant charges the neighboring first region 11 in order to ensure doped regions 17 of the first doping type arranged between the first and second regions are depleted in the off-state.

In the sixth edge region section 126 (not illustrated in FIGS. 14A and 14B) the widths w11, w12 of the first and second regions 11, 12 may decrease in the first lateral direction x in the way illustrated in FIG. 14A and may decrease in the second lateral direction y in the way illustrated in FIG. 14B.

In the example illustrated in FIGS. 15A and 15B, the decrease of the length specific effective dopant charge of the superjunction region 10 in the direction of the edge surface 103 is achieved by implementing the first and second regions 11, 12 such that the depth d11, d12 decreases in the direction of the edge surface 103. In the fourth edge region 124, this includes that at least one first region 11 has a small a depth d11 than another first region 11 arranged closer to the inner region 110. According to one example, at least five first regions 11 have different depths d11 is such that the closer the respective first region 11 is arranged to the edge surface 103, the lower the respective depth d11. Furthermore, this includes that at least one second region 12 has a smaller depth d12 than another second region 12 arranged closer to the inner region 110. According to one example, at least five second regions 12 have different depths d12 is such that the closer the respective first region 12 is arranged to the edge surface 103 the lower the respective depth d12.

According to one example, the transistor device includes pairs with one first region 11 and one neighboring second region 12 in the fourth edge region 124 such that the neighboring first and second regions 11, 12 essentially have the same length specific effective dopant charge. In this way, the effective overall amount of first type dopant charges in the first region 11 essentially equals the effective overall amount of second type dopant charges in the neighboring second region 12, so that the first and second regions 11, 12 can be entirely depleted of charge carries in the off-state. According to one example, the length specific effective dopant charge of the second region 12 in each pair is slightly higher than the length specific effective dopant charge of the neighboring first region 11. This takes into account that the first and second regions 11, 12 may be separated by doped regions 17 of the first doping type. The higher dopant charge in the second regions 12 ensures that these doped regions 12 are depleted in the off-state.

Referring to FIG. 15B, the decrease of the length specific effective dopant charge of the first and second regions 11, 12 in the second lateral direction y in the fifth edge region section 125 includes that the depth d11, d12 of each first and second region 11, 12 decreases towards the edge surface 103 in the second lateral direction y. According to one example, the transistor device includes pairs with one first region 11 and one neighboring second region 12 in the fifth edge region section 125 such that the neighboring first and second regions 11, 12 essentially have the same depth profile.

According to one example, the transistor device includes pairs with one first region 11 and one neighboring second region 12 in the fifth edge region section 125 such that the neighboring first and second regions 11, 12 essentially have the same depth profile, so that the effective overall amount of dopant charges in the neighboring first and second regions 11, 12 is essentially equal. According to one example, each second region 12 at each lateral position in the second lateral direction y is slightly deeper than the neighboring first region 11. In this way, the length specific dopant charge of the second region 12 is higher than the length specific dopant charge of the neighboring first region 11 and the effective overall amount of second type dopant charges in the second region 12 is higher than the effective overall model first type dopant charges in the first region 11 in order to ensure that doped regions 17 of the first doping type arranged between the first and second regions are depleted in the off-state.

In the sixth edge region section 126 (not illustrated in FIGS. 15A and 15B) the depths d11, d12 of the first and second regions 11, 12 may decrease in the first lateral direction x in the way illustrated in FIG. 15A and may decrease in the second lateral direction y in the way illustrated in FIG. 15B.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a source node;
a drain node;
a semiconductor body comprising an inner region and an edge region;
a superjunction region comprising a plurality of first regions of a first doping type and a plurality of second regions of a second doping type arranged alternatingly in a first lateral direction of the semiconductor body;
a plurality of transistor cells arranged in the inner region;
a plurality of current spreading regions of the first doping type each arranged between a respective transistor cell and a respective first region; and
a plurality of third regions of the second doping type arranged in the inner region and the edge region, and spaced apart from each other in the first lateral direction,
wherein the first regions are coupled to the drain node,
wherein each of the third regions is coupled to the source node, adjoins a respective one of the second regions, and, in the inner region, adjoins at least one of the current spreading regions.

2. The transistor device of claim 1, wherein each of the transistor cells comprises:
a gate electrode arranged in a gate trench and connected to a gate node;
a gate dielectric dielectrically insulating the gate electrode from the semiconductor body;
a source region of the first doping type connected to the source node; and
a body region of the second doping type arranged between the source region and a respective one of the current spreading regions.

3. The transistor device of claim 2, further comprising:
a plurality of first connection regions of the second doping type, each connecting at least one of the third regions in the inner region to the source node.

4. The transistor device of claim 3,
wherein each of the first connection regions adjoins the gate dielectric of a respective transistor cell on one side of the gate trench, and the body region of the transistor cell adjoins the gate dielectric on an opposite side of the gate trench.

5. The transistor device of claim 1, further comprising:
a plurality of first connection regions of the second doping type, each connecting at least one of the third regions in the inner region to the source node.

6. The transistor device of claim 1, further comprising:
at least one second connection region of the second doping type connecting the third regions in the edge region to the source node.

7. The transistor device of claim 1,
wherein the edge region comprises a first section, a second section, and a third section,
wherein the first section adjoins the inner region,
wherein the third section adjoins side surfaces of the semiconductor body,
wherein at least portions of some of the third regions and a portion of the superjunction region are arranged in the first section,
wherein a portion of the superjunction region is arranged in the second section,
wherein the second section is devoid of the third regions, and
wherein the third section is devoid of the third regions and the superjunction region.

8. The transistor device of claim 1, further comprising:
a plurality of field rings of the second doping type in the edge region.

9. The transistor device of claim 8,
wherein the edge region comprises a first section, a second section, and a third section,
wherein the first section adjoins the inner region,
wherein the third section adjoins side surfaces of the semiconductor body,
wherein at least portions of some of the third regions and a portion of the superjunction region are arranged in the first section,
wherein a portion of the superjunction region is arranged in the second section,
wherein the second section is devoid of the third regions, and
wherein the third section is devoid of the third regions and the superjunction region,
wherein the field rings are arranged in the second and third sections of the edge region.

10. The transistor device of claim 1,
wherein the third regions in the inner region at least approximately have a same depth, width, and dopant dose as the third regions in the edge region.

11. The transistor device of claim 1,
wherein a lateral dopant charge of the first regions decreases in the edge region towards edge surfaces of the semiconductor body, and
wherein a lateral dopant charge of the second regions decreases in the edge region towards the edge surfaces of the semiconductor body.

12. The transistor device of claim 1, further comprising:
a plurality of inactive transistor cells in the edge region.

13. The transistor device of claim 1, wherein the semiconductor body comprises silicon carbide.

14. The transistor device of claim 1, further comprising:
a drain region of the first doping type,
wherein the drain region is connected to the drain node or forms the drain node, and is coupled to the superjunction region and the drain node.

15. The transistor device of claim 14, further comprising:
a buffer region of the first doping type arranged between the superjunction region and the drain region,
wherein a doping concentration of the buffer region is lower than a doping concentration of the drain region.

16. The transistor device of claim 15, wherein the buffer region comprises:
a first buffer region section adjoining the superjunction region; and
a second buffer region section arranged between the first buffer region section and the drain region,
wherein the first buffer region section has a lower doping concentration than the second buffer region section.

17. The transistor device of claim 1, further comprising:
a source electrode formed above a first surface of the semiconductor body,
wherein the source electrode is connected to the source node or forms the source node, and is connected to source and body regions of the transistor cells.

18. The transistor device of claim 1, further comprising:
a gate runner formed above a first surface of the semiconductor body in the edge region and connected to gate electrodes of the transistor cells.
